(19) United States
(12) Patent Application Publication
(10) Pub. No.: US 2025/0011933 A1
(43) Pub. Date: Jan. 9, 2025

(54) LAMINATE MANUFACTURING APPARATUS AND SELF-ASSEMBLED MONOLAYER FORMATION METHOD

(71) Applicant: TORAY ENGINEERING CO., LTD., Tokyo (JP)

(72) Inventors: Naoto SUGANUMA, Otsu-shi, Shiga (JP); Toyoharu TERADA, Otsu-shi, Shiga (JP); Motohiro YAMAHARA, Kyoto-shi, Kyoto (JP); Kazuyuki NOBORIO, Kyoto-shi, Kyoto (JP); Koshi TAGUCHI, Kyoto-shi, Kyoto (JP)

(21) Appl. No.: 18/547,946

(22) PCT Filed: Jan. 28, 2022
(86) PCT No.: PCT/JP2022/003354

§ 371 Date: Aug. 25, 2023

(30) Foreign Application Priority Data
Mar. 23, 2021 (JP) 2021-048991
Sep. 24, 2021 (JP) 2021-155350

(51) Int. Cl. C23C 16/50; B01J 19/08; C23C 16/448; C23C 16/455; C23C 16/458; C23C 16/52; H01J 37/32

(52) U.S. Cl. CPC C23C 16/50; B01J 19/088; C23C 16/4482; C23C 16/45563; C23C 16/4586; C23C 16/52; H01J 37/3244; H01J 37/32715; B01J 2219/0809; B01J 2219/0869; B01J 2219/0896; H01J 2237/3323

(57) ABSTRACT

A laminate manufacturing apparatus comprises a vacuum chamber, a gas introduction port, and a plasma generator. The laminate manufacturing apparatus has a surface hydrophilization mode in which a film formation surface of a substrate is modified by a plasma atmosphere in a state in which an evaporation source that imparts a hydrophilic group is supplied into the vacuum chamber, thereby rendering the film formation surface hydrophilic, and a self-assembling mode in which an evaporation source of a precursor material of a self-assembled monolayer is supplied to the substrate on which the film formation surface has been hydrophilized, in a state in which an evaporation source that promotes hydrolysis of the precursor material of the self-assembled monolayer has been supplied while an inside of the vacuum chamber is under a vacuum, thereby forming the self-assembled monolayer on the hydrophilized film formation surface.

### CROSS-REFERENCE TO RELATED APPLICATIONS

This application is a U.S. National stage of International Application No. PCT/JP2022/003354 filed on Jan. 28, 2022. This application claims priority to Japanese Patent Application Nos. 2021-048991 filed on Mar. 23, 2021 and 2021-155350 filed on Sep. 24, 2021 with Japan Patent Office. The entire disclosures of Japanese Patent Application Nos. 2021-048991 and 2021-155350 are hereby incorporated herein by reference.

### BACKGROUND

### Field of the Invention

The present invention relates to a laminate manufacturing apparatus and a method for forming a self-assembled monolayer.

### Background Information

In various fields such as automobile parts and electronic parts, there is a need to perform surface treatment, such as improving adhesion to adhesive layers and coating layers, and rendering a resin surface hydrophilic, water repellent, lipophilic, antifouling, etc. In view of this, the conventional practice has been to perform a plasma treatment to improve adhesion to an adhesive layer or a coating layer, or to render a resin surface hydrophilic or water-repellent. However, especially with hydrophilization, a problem is that plasma treatment alone results in changes over time, and in some materials the effect ends up being reduced to about half of the effect immediately after treatment within just a few hours. Also, recently there has been an increasing demand for preservation, and even extension, of the treatment effect.

Meanwhile, thin films for functional coating are currently being used for various purposes. One of these is a self-assembled monolayer (hereinafter also referred to as an SAM film). One of the possible forms of an SAM film is to add polar groups (hydrophilic groups) such as hydroxyl groups or carboxyl groups to a substrate surface, and allow a metal alkoxide-based material, an organosilane-based material, or an organophosphonic acid-based material to self-assemble to form a single-layer film. With metal alkoxide-based materials and organosilane-based materials, products after a hydrolysis reaction are assembled by hydrogen bonds with polar groups on the substrate surface, and are covalently bonded by a dehydration condensation reaction. Also, in the case of an organophosphonic acid-based material, it forms a salt with the polar groups on the substrate surface of a basic or neutral oxide, and is covalently bonded by a dehydration condensation reaction.

SAM film production methods can be broadly classified into wet processes and dry processes. The former is called a sol-gel method, and makes use of an acid or base catalyst in an alcohol-based organic solvent. An alcohol solution in which the metal alkoxide or alkoxyorganosilane has been dissolved and an alcohol solution in which water has been dissolved are prepared separately, a catalyst is dissolved in the aqueous solution, and the two are mixed to promote a hydrolysis reaction. After this, the solution is applied by dip coating, spray coating, or spin coating, and the solvent is evaporated to allow the dehydration condensation reaction to proceed.

By contrast, a dry process is based on vacuum technology or electrical discharge technology, and can form an SAM film without the use of any solvents or catalysts. Hydrophilic groups such as hydroxyl groups and carboxyl groups are added to the substrate surface by plasma treatment of water, oxygen, or the like in a vacuum plasma device, and then a vapor phase metal alkoxide material or alkoxyorganosilane material is supplied, which allows the hydrolysis dehydration condensation reaction to proceed.

Japanese Patent Application Publication No. 2003-276110 (Patent Literature 1) indicates that a polyethylene terephthalate (PET) substrate is irradiated with a mixed gas plasma of tetramethoxysilane and oxygen from a high-frequency plasma device to produce a silicon dioxide film having hydroxyl groups on its surface, after which the PET substrate having the silicon dioxide film is left in a 100° C. oven for 5 hours along with octadecyltrimethoxysilane to form a hydrophobic SAM film.

Japanese Patent Application Publication No. 2004-98350 (Patent Literature 2) indicates that a polyethylene terephthalate (PET) substrate is irradiated with an oxygen gas plasma from a high-frequency plasma device to form texturing on the surface of the PET substrate, and at the same time, hydroxyl groups (adsorption groups) are added, after which the substrate is irradiated with a mixed gas plasma of tetraethoxysilane and oxygen to form a hydrophilic SAM film.

International Publication No. WO 2017/069221 (Patent Literature 3) describes an apparatus for manufacturing an SAM film, which has a chamber having electrodes, and with which Si—H bonds are introduced to the surface while a direct current is applied, and an SAM film of a vinyl derivative is formed.

Japanese Patent No. 6,265,496 (Patent Literature 4) describes an apparatus with which a plasma produced from a high-frequency plasma source is used to perform a remote treatment aimed at cleaning the surface of a sample substrate before forming an SAM film on the sample substrate, and the SAM film is formed after this.

### SUMMARY

There has been rising demand in recent years for laminates that have undergone surface treatment for water repellency, oil repellency, lipophilicity, hydrophilicity, antifouling properties, and so forth in the field of surface treatment.

However, as in Patent Literature 2, with a plasma treatment in which etching is performed to form texturing on the surface of a sample, an inherent problem is that this accelerates deterioration of the base material.

Also, Patent Literature 3 indicates that a plasma treatment used as a pretreatment to a SAM film formation process is performed in a separate apparatus, which poses a problem in terms of the extra labor entailed by the movement of the sample substrate.

Furthermore, with the configuration described in Patent Literature 4, remote plasma treatment is performed as a cleaning step, but a problem is that the force at which hydrophilic groups such as hydroxyl groups are imparted to the substrate surface is weak, and the hydrophilic groups do not reach the desired density.

It is an object of the present invention to provide a laminate manufacturing apparatus with which a high-density SAM film can be formed a dry process, and the entire film formation process, from substrate pretreatment to completion of high-density SAM film formation, can be carried out simply, as well as a method for forming a self-assembled monolayer.

The laminate manufacturing apparatus according to the present invention is a laminate manufacturing apparatus for forming a self-assembled monolayer on a film formation surface of a substrate, said apparatus comprising a vacuum chamber in which a substrate is housed, a gas introduction port for introducing a gas into the vacuum chamber, and a plasma generator that forms a plasma atmosphere in the vacuum chamber, wherein the apparatus has a surface hydrophilization mode in which the film formation surface of the substrate is modified by the plasma atmosphere generated by the plasma generator in a state in which an evaporation source that imparts hydrophilic groups is supplied into the vacuum chamber, thereby rendering the film formation surface hydrophilic, and a self-assembling mode in which an evaporation source for a precursor material of a self-assembled monolayer is supplied to the substrate on which the film formation surface has been hydrophilized, in a state in which an evaporation source that promotes the hydrolysis of the precursor material for the self-assembled monolayer has been supplied while the inside of the vacuum chamber is under a vacuum, thereby forming the self-assembled monolayer on the hydrophilized film formation surface.

The method for forming a self-assembled monolayer according to the present invention is a method for forming a self-assembled monolayer on the surface of a substrate, comprising a step A of disposing the substrate in a vacuum chamber, a step B of supplying an evaporation source that imparts hydrophilic groups to the surface of the substrate into the vacuum chamber, and plasmatizing the interior of the vacuum chamber to generate a plasma of the evaporation source and render the substrate surface hydrophilic, and a step C of supplying an evaporation source of a precursor material of the self-assembled monolayer into the vacuum chamber in a state in which an evaporation source that promotes hydrolysis of the precursor material of the self-assembled monolayer has been supplied after step B, thereby forming the self-assembled monolayer on the surface of the substrate, wherein the steps B and C are performed without opening the vacuum chamber to the atmosphere.

With the present invention, the substrate surface immediately prior to the formation of an SAM film on the substrate is subjected to a vacuum plasma treatment, which allows hydrophilic groups such as hydroxyl groups to be imparted in a high density without forming any texturing on the surface, and furthermore, a high-density SAM film can be formed before the hydrophilicity of the substrate changes over time due to the hydrophilic groups imparted to the substrate.

Also, with the present invention, the step of forming the SAM film in the vacuum chamber can be performed immediately after the hydrophilic treatment of the substrate with a high-frequency vacuum plasma, which makes it easier to activate the SAM precursor supplied in the SAM film formation process, and makes it possible to promote the dehydration condensation reaction with the hydrophilic group imparted to the substrate.

Furthermore, with the present invention, sine an SAM film is formed by a dry process, and the entire film formation process, from substrate pretreatment to completion of SAM film formation in a high density, can be performed simply, so the manufacturing cost can be lowered and an SAM film can be formed simply and easily.

### BRIEF DESCRIPTION OF THE DRAWINGS

FIG. 1 is a schematic diagram of the overall configuration of the laminate manufacturing apparatus for manufacturing a laminate according to an embodiment of the present invention;

FIG. 2 is a cross-sectional view of the vacuum chamber of the laminate manufacturing apparatus for manufacturing a laminate according to an embodiment of the present invention;

FIG. 3 is a schematic diagram of the overall configuration of the laminate manufacturing apparatus for manufacturing a laminate according to Modification Example 1 of an embodiment of the present invention;

FIG. 4 is a schematic diagram of the overall configuration of the laminate manufacturing apparatus for manufacturing a laminate according to Modification Example 2 of an embodiment of the present invention; and

FIG. 5 is a schematic diagram of the overall configuration of the laminate manufacturing apparatus for manufacturing a laminate according to Modification Example 3 of an embodiment of the present invention.

### DETAILED DESCRIPTION OF EMBODIMENTS

An embodiment of the present invention will now be described with reference to the drawings.

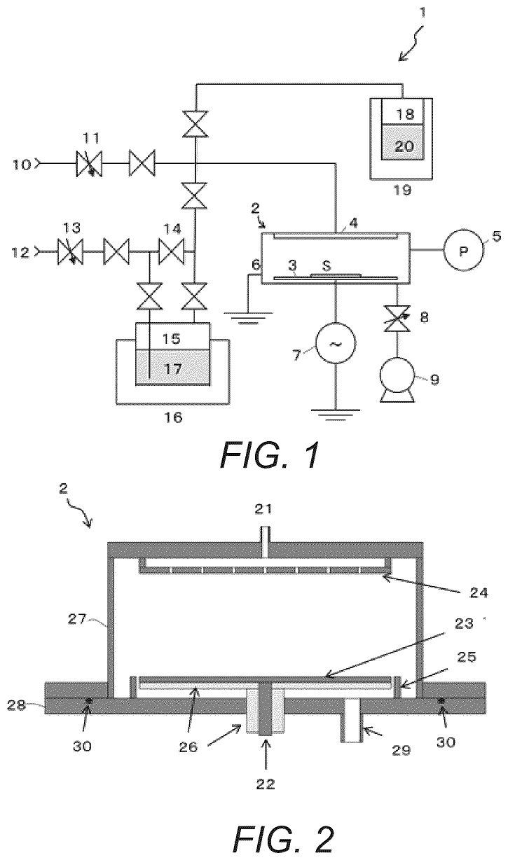

FIG. 1 is a schematic diagram of the overall configuration of the laminate manufacturing apparatus according to an embodiment. FIG. 2 is a cross-sectional view of the vacuum chamber of the laminate manufacturing apparatus in an embodiment.

The laminate manufacturing apparatus 1 according to this embodiment is an apparatus for forming an SAM film on a film formation surface of a substrate.

In this embodiment, a substrate S having at least two sides is used as the substrate. There are no particular restrictions on the material constituting the substrate S, but examples include SiO₂ (glass), silicon, alumina, ceramic, sapphire, and other such inorganic materials, and plastics, films, and other such organic materials. The substrate S may be one that has undergone a wet cleaning process.

As shown in FIG. 1, the laminate manufacturing apparatus 1 has a vacuum chamber 2 that accommodates a substrate S, a lower electrode 3 that also serves as a sample stage for disposing the substrate S in the vacuum chamber 2, and an upper electrode 4 that is opposite the lower electrode 3, and the lower electrode 3 is connected to a power source 7 for plasma generation. Although the lower electrode 3 also serves as the sample stage in FIG. 1, the upper electrode 4 may instead also serve as the sample stage, or both the lower electrode 3 and the upper electrode 4 may also serve as the sample stage. Also, the power supply 7 for plasma generation may be a low-frequency power supply, or may be a high-frequency power supply. Furthermore, a pressure gauge 5 for monitoring the pressure inside the vacuum chamber 2, a ground 6, and a vacuum pump 9 are connected to the vacuum chamber 2. In addition, a gas introduction port 10 used in plasma treatment, a bubbler 15 for reactant materials required in the plasma treatment and in the SAM film formation process, and a raw material chamber 18 for the SAM film are connected by pipes so that materials can be introduced into the vacuum chamber 2.

Furthermore, as shown in FIG. 2, the vacuum chamber 2 in this embodiment has an upper chamber 27 and a lower chamber 28, and the lower chamber 28 has an O-ring 30.

In this embodiment, the upper chamber 27 and the lower chamber 28 are constituted by electrically grounded electrical conductors, and the entire inner wall surface of the vacuum chamber 2 serves as a ground potential surface whose potential is grounded. The electrical conductors constituting the upper chamber 27 and the lower chamber 28 are metal materials composed of, for example, copper, nickel, titanium, or another such transition metal, alloys of these, or stainless steel, molybdenum, tungsten, or another such refractory metal.

In this embodiment, a gas introduction part 21 is provided to the upper part of the upper chamber 27, and the gas introduction port 10 used for plasma treatment, the bubbler 15 for reactant substance necessary for plasma treatment and the SAM film formation process, and a pipe connected from the raw material chamber 18 for the SAM film are connected to the gas introduction part 21.

In this embodiment, the lower electrode 3 that also serves as a sample stage is constituted by a current introduction terminal 22 and an electrode stage 23, and an insulating member 26 is disposed around the current introduction terminal 22 and under the electrode stage 23. Also, the current introduction terminal 22 is connected to the high-frequency power supply 7. The upper electrode 4 opposite the lower electrode 3 has a structure that also serves as a gas shower plate 24.

In this embodiment, the lower chamber 28 has a structure in which a ground ring 25 is provided so as to surround the electrode stage 23. The height difference between the electrode stage 23 and the ground ring 25 is preferably about 0 mm, and the ground ring 25 is preferably higher than the electrode stage 23. The ground ring 25 is formed so that its spacing from the electrode stage 23 is at least 1 mm and no more than 5 mm. This spacing allows the flow of gas to be controlled and the uniform region of the plasma to be as wide as possible.

If the spacing between the ground ring 25 and the electrode stage 23 is less than 1 mm, the spacing will be too narrow to draw gas sufficiently when gas is drawn by the vacuum pump, and moreover, abnormal discharge will occur, preventing the desired plasma from being generated. Also, if the spacing between the ground ring 25 and the electrode stage 23 is greater than 5 mm, abnormal discharge will occur between the electrode stage 23 and the ground ring 25, making it impossible to generate the desired uniform plasma.

Also, the lower chamber 28 has a vacuum exhaust port 29 between the current introduction terminal 22 and the ground ring 25, is connected to the vacuum pump 9, and is configured such that the degree of vacuum is adjusted by an exhaust flow control valve 8. Therefore, using the apparatus of this embodiment makes it possible to properly perform a hydrophilization treatment by plasma treatment in the pretreatment step of forming an SAM film.

This embodiment is configured such that a gas used for plasma treatment is introduced through the gas introduction port 10, and is connected to a three-system gas introduction pipe of the bubbler 15 for the reactant substance required in the plasma treatment and the SAM film formation process, and the raw material chamber 18. A piping structure surrounded by a heat insulating material (not shown) or a heater (not shown) is used for the gas introduction pipe so that the gas does not liquefy.

In this embodiment, the gas used for plasma treatment that is introduced through the gas introduction port 10 is supplied from a gas cylinder (not shown) and introduced into the vacuum chamber 2 via a flow control valve/mass flow controller 11. A gas that imparts hydroxyl groups (OH groups) to the surface of the sample S or a pretreatment gas for the step of imparting OH groups is selected as the gas used for the plasma treatment. Examples include water vapor (H₂O), oxygen (O₂), and argon (Ar). There are no limitations on this gas so long as it is a gas that imparts OH groups to the surface or a gas that can be used for pretreatment to the step of imparting OH.

When the gas used for plasma treatment is supplied to the vacuum chamber 2, the degree of vacuum in the vacuum chamber 2 is controlled by the exhaust flow control valve 8 and the vacuum pump 9, and discharge from the lower electrode 3 and the upper electrode 4 causes the gas to function as a plasma generation gas, and the sample S is subjected to a plasma hydrophilization treatment.

In this embodiment, the bubbler 15, which is filled with a vapor source 17, which is a reactant substance necessary for plasma treatment or for the SAM film formation process, is provided with a mantle heater 16, and this heating generates a vapor of the vapor source 17, which is a reactant substance necessary for plasma treatment or for the SAM film formation process, and this vapor is supplied to the vacuum chamber 2. The bubbler 15 is connected to a pipe to which is supplied a carrier gas from a carrier gas introduction port 12 for carrying the vapor of the vapor source 17, via the flow control valve/mass flow controller 13, and the piping is configured to have a bypass valve 14 through which the carrier gas that can be mixed with the vapor from the bubbler passes, without passing through the bubbler 15. If no carrier gas is needed, the carrier gas need not be supplied.

An evaporation source that imparts OH groups to the surface of the sample S, or an evaporation source that promotes hydrolysis of the precursor of the SAM film is selected as the vapor source 17, which is a reactant substance necessary for the plasma treatment and for the SAM film formation process. Water (H₂O) is one example, and what is used most often.

When the vapor source 17, which is a reactant substance necessary for the plasma treatment and the SAM film formation process, is supplied to the vacuum chamber 2, the H₂O gas (water vapor) functions as a plasma generation gas upon discharge between the lower electrode 3 and the upper electrode 4, and this becomes a step of imparting OH groups to the surface of the sample S. In the SAM film formation step that follows immediately after this, the residual component (water vapor) of the plasma during discharge promotes the hydrolysis reaction with the SAM precursor material. As to the hydrolysis reaction of the SAM precursor, in which the vacuum chamber 2 is maintained at the same degree of vacuum by the flow control valve 8 and the vacuum pump 9, this reaction may occur either during the discharge or after the discharge has been halted.

In this embodiment, the SAM film raw material chamber 18 into which the vapor source 20 for the SAM precursor material is introduced is provided with the mantle heater 19, and this heating generates a vapor in the chamber 18 for the SAM film raw material, and this vapor is supplied to the vacuum chamber 2. An evaporation source for dehydration condensation between the OH groups formed on the surface of the sample S and the OH groups produced by hydrolysis of the precursor material of the SAM film, or an evaporation source for dehydration condensation between the OH groups formed on the surface of the sample S by the molecules themselves of the evaporation source of the SAM precursor material, is selected as the vapor source 20 for the SAM precursor material. Examples include 1H,1H,2H,2H-perfluorodecyldimethylchlorosilane, tetrahydrooctylmethyldichlorosilane (FOMDS), dichlorodimethylsilane (DDMS), 1H,1H,2H,2H-perfluorodecyltrichlorosilane (FDTS), octadecyltrichlorosilane (OTS), tetrahydrooctyltrichlorosilane (FOTS), and other such chlorosilane-based compounds, dimethyldimethoxysilane, dimethyldiethoxysilane, isobutylmethyldimethoxysilane, hexyltrimethoxysilane, hexyltriethoxysilane, dodecyltriethoxysilane, 1H,1H,2H,2H-perfluorodecyltrimethoxysilane, n-octadecyltrimethoxysilane, tetraethoxysilane (TEOS), and other such alkoxysilane compounds, octadecylphosphonic acid, 1H,1H,2H,2H-perfluoro-octylphosphonic acid, and other such phosphonic acid-based materials, and hexamethyldisilazane (HMDS) and other such disilazane-based compounds. There are no restrictions on the material so long as it is a chlorosilane-based material, alkoxysilane-based material, phosphonic acid-based material, or disilazane-based material that can form an SAM film.

When the vapor source 20 for the SAM precursor material is supplied to the vacuum chamber 2, there may or may not be a discharge between the lower electrode 3 and the upper electrode 4. In the SAM film formation process, if the vapor source 20 of the SAM precursor material is a chlorosilane-based material, an alkoxysilane-based material, or a disilazane-based material, the residual component of the plasma during discharge and H₂O undergo a hydrolysis reaction with the SAM precursor material, after which the OH groups imparted to the sample surface and the OH groups of the adjacent SAM precursor undergo self-assembly with hydrogen bonds, after which a dehydration condensation reaction proceeds to form an SAM film. If the vapor source 20 of the SAM precursor material is a phosphonic acid material, hydrolysis is not required and the dehydration condensation reaction proceeds directly to form the SAM film.

As described above, the laminate manufacturing apparatus according to this embodiment comprises a plasma generator that forms a plasma atmosphere in the vacuum chamber, and has modes for executing the following two treatments.

(1) Surface hydrophilization mode: In a state in which an evaporation source that imparts hydrophilic groups has been supplied into the vacuum chamber, the film formation surface of the substrate is modified by the plasma atmosphere formed by the plasma generator to render the film formation surface hydrophilic.
(2) Self-assembly mode: In a state in which an evaporation source that promotes hydrolysis of the precursor material of the SAM film has been supplied to a substrate whose film formation surface has been rendered hydrophilic, while the vacuum chamber is under a vacuum, an evaporation source of the precursor material of the SAM film is supplied to form an SAM film on a hydrophilic film formation surface.

In this embodiment, the surface hydrophilization mode and the self-assembly mode are preferably performed in the same vacuum chamber. Doing this allows the transition from the surface hydrophilization mode to the self-assembling mode to be made without exposing the vacuum chamber to the atmosphere. If the surface hydrophilization mode and the self-assembling mode are performed in separate vacuum chambers, it is preferable to use a load-lock type of vacuum chamber that allows the substrate to be transported while a vacuum state is maintained.

In this embodiment, the evaporation source that imparts hydroxyl groups to the surface of the substrate and the evaporation source that promotes hydrolysis of the precursor material of the self-assembled monolayer are preferably both water vapor. The water vapor in the self-assembling mode may be water vapor left behind from the surface hydrophilization mode.

With this embodiment, the substrate surface is subjected to a vacuum plasma treatment immediately before forming the SAM film on the substrate, which allows hydrophilic groups such as hydroxyl groups to be imparted in a high density, and also allows a high-density SAM film to be formed on the substrate surface before the hydrophilicity of the substrate is changed over time by the hydrophilic groups imparted to the substrate, without exposing the vacuum chamber to the atmosphere.

Also, the method for forming an SAM film in this embodiment includes a step A of disposing the substrate in a vacuum chamber, a step B of supplying an evaporation source that imparts hydrophilic groups to the surface of the substrate into the vacuum chamber, and plasmatizing the interior of the vacuum chamber to generate a plasma of the evaporation source and render the substrate surface hydrophilic, and a step C of supplying an evaporation source of a precursor material of the self-assembled monolayer into the vacuum chamber in a state in which an evaporation source that promotes hydrolysis of the precursor material of the self-assembled monolayer has been supplied after step B, thereby forming the self-assembled monolayer on the surface of the substrate, wherein steps B and C are performed without opening the vacuum chamber to the atmosphere.

Configuration changes are possible in this embodiment. Modification examples of the above embodiment will be described below.

### Modification Example 1

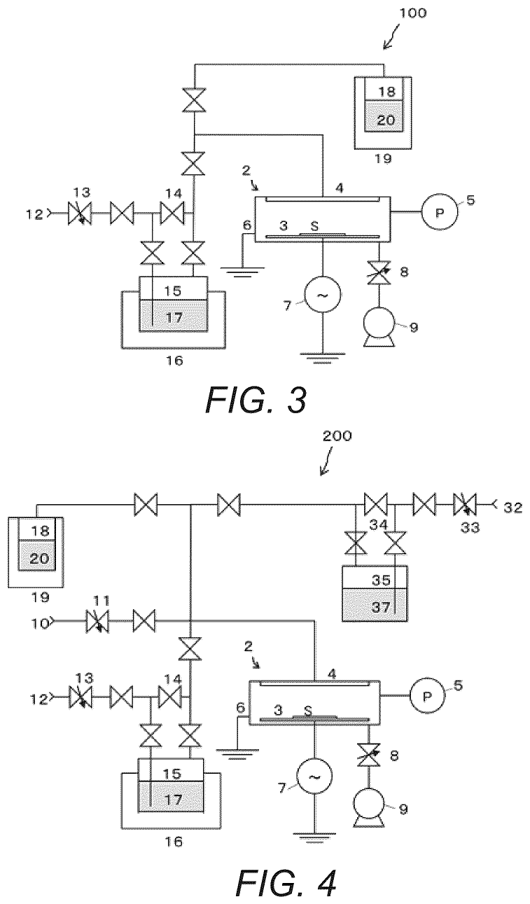

The laminate manufacturing apparatus 100 of Modification Example 1 will now be described with reference to FIG. 3.

The laminate manufacturing apparatus 100 in Modification Example 1 is configured to be connected to a two-system gas introduction pipe of the bubbler 15 for the reactant substance required for plasma treatment and the SAM film formation process, and the SAM film raw material chamber 18. FIG. 1 shows a configuration having no pipe from the gas introduction port 10. The gas introduction pipe is surrounded by a heat insulating material (not shown) or a heater (not shown) so that the gas will not liquefy.

In Modification Example 1, a vapor source 17, which is a reactant material required for the plasma treatment and the SAM film formation process, is introduced into the bubbler 15. The bubbler 15 is equipped with a mantle heater 16, which generates vapor from the vapor source 17, which is a reactant material required for plasma treatment and the SAM film formation process, when heated, and supplies this vapor to the vacuum chamber 2. The bubbler 15 is linked to a pipe through which a carrier gas is supplied from a carrier gas introduction port 12 for carrying the vapor of the vapor source 17, through a flow control valve/mass flow controller 13, and the piping is configured to have a bypass valve 14 through which the carrier gas that can be mixed with the vapor from the bubbler passes, without passing through the bubbler 15. If no carrier gas is required, the carrier gas need not be supplied.

The vapor source 17, which is a reactant material necessary for the plasma treatment and for the SAM film formation process, is an evaporation source that imparts OH groups to the surface of the sample S by means of a plasma of the vapor source 17, and an evaporation source is selected that promotes hydrolysis of the precursor of the SAM film. Water (H₂O) is one example, and what is used most often.

In Modified Example 1, when the vapor source 17, which is a reactant substance necessary for the plasma treatment and the SAM film formation process, is supplied to the vacuum chamber 2, a discharge is generated between the lower electrode 3 and the upper electrode 4, and as a result the H₂O gas (water vapor) functions as a plasma generation gas, and OH groups are imparted to the surface of the sample S. In the SAM film formation step that immediately follows, the residual component of the plasma from during this discharge promotes a hydrolysis reaction with the SAM precursor material.

This configuration can be used when the sample S is a material capable of imparting OH groups to the surface only by a plasma treatment of the H₂O gas (water vapor). As to the hydrolysis reaction of the SAM precursor, in which the vacuum chamber 2 is maintained at the same degree of vacuum by the flow control valve 8 and the vacuum pump 9, this reaction may occur either during the discharge or after the discharge has been halted.

In Modification Example 1, the SAM film raw material chamber 18 into which the vapor source 20 for the SAM precursor material is introduced is provided with the mantle heater 19, and this heating generates a vapor in the raw material chamber 18 for the SAM film raw material, and this vapor is supplied to the vacuum chamber 2. An evaporation source for dehydration condensation between the OH groups formed on the surface of the sample S and the OH groups produced by hydrolysis of the precursor material of the SAM film, or an evaporation source for dehydration condensation between the OH groups formed on the surface of the sample S by the molecules themselves of the evaporation source of the SAM precursor material, is selected as the vapor source 20 for the SAM precursor material. Examples include 1H,1H,2H,2H-perfluorodecyldimethylchlorosilane, tetrahydrooctylmethyldichlorosilane (FOMDS), dichlorodimethylsilane (DDMS), 1H,1H,2H,2H-perfluorodecyltrichlorosilane (FDTS), octadecyltrichlorosilane (OTS), tetrahydrooctyltrichlorosilane (FOTS), and other such chlorosilane-based compounds, dimethyldimethoxysilane, dimethyldiethoxysilane, isobutylmethyldimethoxysilane, hexyltrimethoxysilane, hexyltriethoxysilane, dodecyltriethoxysilane, 1H,1H,2H,2H-perfluorodecyltrimethoxysilane, n-octadecyltrimethoxysilane, tetraethoxysilane (TEOS), and other such alkoxysilane compounds, octadecylphosphonic acid, 1H,1H,2H,2H-perfluoro-octylphosphonic acid, and other such phosphonic acid-based materials, and hexamethyldisilazane (HMDS) and other such disilazane-based compounds. There are no restrictions on the material so long as it is a chlorosilane-based material, alkoxysilane-based material, phosphonic acid-based material, or disilazane-based material that can form an SAM film.

### Modification Example 2

The laminate manufacturing apparatus 200 of Modification Example 2 will be described below with reference to FIG. 4.

The laminate manufacturing apparatus 200 in Modification Example 2 is configured such that a gas used for plasma treatment is introduced through the gas introduction port 10, and is connected to a four-system gas introduction pipe of the bubbler 15 for the reactant substance required for the plasma treatment and the SAM film formation process, the SAM film raw material chamber 18, and a bubbler 35 that is the same as the bubbler 15 for the reactant material required for the plasma treatment and SAM film formation process, and that is added as a bubbler for the raw material of the SAM film. The gas introduction pipe is surrounded by a heat insulating material (not shown) or a heater (not shown) so that the gas will not liquefy.

In Modification Example 2, the gas used for plasma treatment introduced through the gas introduction port 10 is supplied from a gas cylinder (not shown) and is introduced into the vacuum chamber 2 via the flow control valve/mass flow controller 11. A gas that imparts hydroxyl groups (OH groups) to the surface of the sample S or a pretreatment gas for the step of imparting OH groups is selected as the gas used for the plasma treatment. Examples include water vapor (H₂O), oxygen (O₂), and argon (Ar). There are no limitations on this gas so long as it is a gas that imparts OH groups to the surface or a gas that can be used for pretreatment to the step of imparting OH.

When the gas used for plasma treatment is supplied to the vacuum chamber 2, the degree of vacuum in the vacuum chamber 2 is controlled by the exhaust flow control valve 8 and the vacuum pump 9, and discharge from the lower electrode 3 and the upper electrode 4 causes the gas to function as a plasma generation gas, and the sample S is subjected to a plasma hydrophilization treatment.

In Modified Example 2, the bubbler 15, which is filled with the vapor source 17, which is a reactant substance necessary for plasma treatment or for the SAM film formation process, is provided with the mantle heater 16, and this heating generates a vapor of the vapor source 17, which is a reactant substance necessary for plasma treatment or for the SAM film formation process, and this vapor is supplied to the vacuum chamber 2. The bubbler 15 is connected to a pipe to which is supplied a carrier gas from a carrier gas introduction port 12 for carrying the vapor of the vapor source 17, via the flow control valve/mass flow controller 13, and the piping is configured to have a bypass valve 14 through which the carrier gas that can be mixed with the vapor from the bubbler passes, without passing through the bubbler 15. If no carrier gas is needed, the carrier gas need not be supplied.

An evaporation source that imparts OH groups to the surface of the sample S, or an evaporation source that promotes hydrolysis of the precursor of the SAM film is selected as the vapor source 17, which is a reactant substance necessary for the plasma treatment and for the SAM film formation process. Water (H₂O) is one example, and what is used most often.

In Modified Example 2, the SAM film raw material chamber 18 into which the vapor source 20 for the SAM precursor material is introduced is provided with the mantle heater 19, and this heating generates a vapor in the SAM film raw material chamber 18, and this vapor is supplied to the vacuum chamber 2. An evaporation source for dehydration condensation between the OH groups formed on the surface of the sample S and the OH groups produced by hydrolysis of the precursor material of the SAM film, or an evaporation source for dehydration condensation between the OH groups formed on the surface of the sample S by the molecules themselves of the evaporation source of the SAM precursor material, is selected as the vapor source 20 for the SAM precursor material. Examples include 1H,1H,2H,2H-perfluorodecyldimethylchlorosilane, tetrahydrooctylmethyldichlorosilane (FOMDS), dichlorodimethylsilane (DDMS), 1H,1H,2H,2H-perfluorodecyltrichlorosilane (FDTS), octadecyltrichlorosilane (OTS), tetrahydrooctyltrichlorosilane (FOTS), and other such chlorosilane-based compounds, dimethyldimethoxysilane, dimethyldiethoxysilane, isobutylmethyldimethoxysilane, hexyltrimethoxysilane, hexyltriethoxysilane, dodecyltriethoxysilane, 1H,1H,2H,2H-perfluorodecyltrimethoxysilane, n-octadecyltrimethoxysilane, tetraethoxysilane (TEOS), and other such alkoxysilane compounds, octadecylphosphonic acid, 1H,1H,2H,2H-perfluoro-octylphosphonic acid, and other such phosphonic acid-based materials, and hexamethyldisilazane (HMDS) and other such disilazane-based compounds. There are no restrictions on the material so long as it is a chlorosilane-based material, alkoxysilane-based material, phosphonic acid-based material, or disilazane-based material that can form an SAM film.

In Modification Example 2, the bubbler 35 into which the vapor source 37 of the SAM precursor material is introduced is used, for example, when supplying a vapor of the SAM film raw material to the chamber 2 by allowing a carrier gas such as nitrogen (N₂) to flow, without heating the SAM film raw material. The bubbler 35 is connected to a pipe through which the carrier gas is supplied from a carrier gas introduction port 32 for carrying a vapor of the vapor source 37 via a flow control valve/mass flow controller 33, and the piping is configured to have a bypass valve 34 through which the carrier gas that can be mixed with the vapor from the bubbler passes, without passing through the bubbler 35. If no carrier gas is required, the carrier gas need not be supplied.

With the SAM film raw material bubbler 35, an evaporation source for dehydration condensation between the OH groups formed on the surface of the sample S and the OH groups produced by hydrolysis of the precursor material of the SAM film, or an evaporation source for dehydration condensation between the OH groups formed on the surface of the sample S by the molecules themselves of the evaporation source of the SAM precursor material, is selected as the vapor source 37 for the SAM precursor material. Examples include 1H,1H,2H,2H-perfluorodecyldimethylchlorosilane, tetrahydrooctylmethyldichlorosilane (FOMDS), dichlorodimethylsilane (DDMS), 1H,1H,2H,2H-perfluorodecyltrichlorosilane (FDTS), octadecyltrichlorosilane (OTS), tetrahydrooctyltrichlorosilane (FOTS), and other such chlorosilane-based compounds, dimethyldimethoxysilane, dimethyldiethoxysilane, isobutylmethyldimethoxysilane, hexyltrimethoxysilane, hexyltriethoxysilane, dodecyltriethoxysilane, 1H,1H,2H,2H-perfluorodecyltrimethoxysilane, n-octadecyltrimethoxysilane, tetraethoxysilane (TEOS), and other such alkoxysilane compounds, octadecylphosphonic acid, 1H,1H,2H,2H-perfluoro-octylphosphonic acid, and other such phosphonic acid-based materials, and hexamethyldisilazane (HMDS) and other such disilazane-based compounds. There are no restrictions on the material so long as it is a chlorosilane-based material, alkoxysilane-based material, phosphonic acid-based material, or disilazane-based material that can form an SAM film.

### Modification Example 3

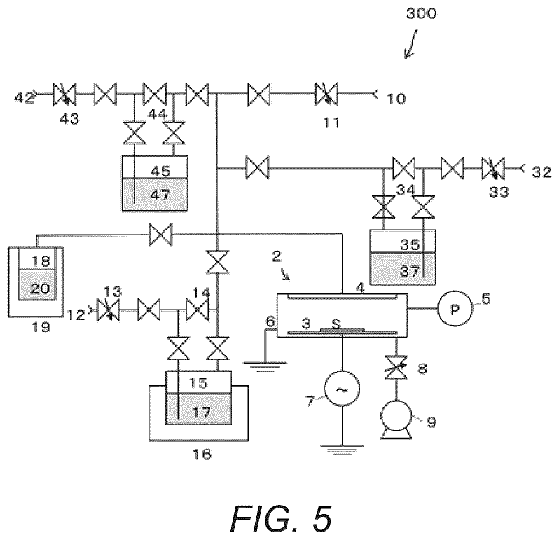

The laminate manufacturing apparatus 300 of Modification Example 3 will be described below with reference to FIG. 5.

The laminate manufacturing apparatus 300 according to Modification Example 3 is configured such that a gas used for plasma treatment is introduced through the gas introduction port 10, and is connected to a five-system gas introduction pipe of the bubbler 15 for the reactant substance required for the plasma treatment and the SAM film formation process, the raw material chamber 18 for the SAM film, and bubblers 35 and 45 that are the same as the bubbler 15 for the reactant material required for the plasma treatment and SAM film formation process, and that are added as bubblers for the raw material of the SAM film. A piping structure surrounded by a heat insulating material (not shown) or a heater (not shown) is used for the gas introduction pipe so that the gas does not liquefy.

In the laminate manufacturing apparatus 300 of Modification Example 3, when performing hydrophilic, water-repellent, lipophilic, or oil-repellent patterning, by changing the type of SAM film with a mask or the like on the sample S, an SAM film can be easily formed by continuously changing the type of evaporation source of the film raw material.

In Modification Example 3, the gas used for plasma treatment that is introduced through the gas introduction port 10 is supplied from a gas cylinder (not shown) and introduced into the vacuum chamber 2 via the flow control valve/mass flow controller 11. A gas that imparts hydroxyl groups (OH groups) to the surface of the sample S or a pretreatment gas for the step of imparting OH groups is selected as the gas used for the plasma treatment. Examples include oxygen (O₂) and argon (Ar). There are no limitations on this gas so long as it is a gas that imparts OH groups to the surface or a gas that can be used for pretreatment to the step of imparting OH.

When the gas used for plasma treatment is supplied to the vacuum chamber 2, the degree of vacuum in the vacuum chamber 2 is controlled by the exhaust flow control valve 8 and the vacuum pump 9, and discharge from the lower electrode 3 and the upper electrode 4 causes the gas to function as a plasma generation gas, and the sample S is subjected to a plasma hydrophilization treatment.

In Modified Example 3, the bubbler 15, which is filled with the vapor source 17, which is a reactant substance necessary for plasma treatment or for the SAM film formation process, is provided with the mantle heater 16, and this heating generates a vapor of the vapor source 17, which is a reactant substance necessary for plasma treatment or for the SAM film formation process, and this vapor is supplied to the vacuum chamber 2. The bubbler 15 is connected to a pipe to which is supplied a carrier gas from a carrier gas introduction port 12 for carrying the vapor of the vapor source 17, via the flow control valve/mass flow controller 13, and the piping is configured to have the bypass valve 14 through which the carrier gas that can be mixed with the vapor from the bubbler passes, without passing through the bubbler 15. If no carrier gas is needed, the carrier gas need not be supplied.

An evaporation source that imparts OH groups to the surface of the sample S, or an evaporation source that promotes hydrolysis of the precursor of the SAM film is selected as the vapor source 17, which is a reactant substance necessary for the plasma treatment and for the SAM film formation process. Water (H₂O) is one example, and what is used most often.

In Modification Example 3, the SAM film raw material chamber 18 into which the vapor source 20 for the SAM precursor material is introduced is provided with the mantle heater 19, and this heating generates a vapor in the SAM film raw material chamber 18, and this vapor is supplied to the vacuum chamber 2. An evaporation source for dehydration condensation between the OH groups formed on the surface of the sample S and the OH groups produced by hydrolysis of the precursor material of the SAM film, or an evaporation source for dehydration condensation between the OH groups formed on the surface of the sample S by the molecules themselves of the evaporation source of the SAM precursor material, is selected as the vapor source 20 for the SAM precursor material. Examples include 1H,1H,2H,2H-perfluorodecyldimethylchlorosilane, tetrahydrooctylmethyldichlorosilane (FOMDS), dichlorodimethylsilane (DDMS), 1H,1H,2H,2H-perfluorodecyltrichlorosilane (FDTS), octadecyltrichlorosilane (OTS), tetrahydrooctyltrichlorosilane (FOTS), and other such chlorosilane-based compounds, dimethyldimethoxysilane, dimethyldiethoxysilane, isobutylmethyldimethoxysilane, hexyltrimethoxysilane, hexyltriethoxysilane, dodecyltriethoxysilane, 1H,1H,2H,2H-perfluorodecyltrimethoxysilane, n-octadecyltrimethoxysilane, tetraethoxysilane (TEOS), and other such alkoxysilane compounds, octadecylphosphonic acid, 1H,1H,2H,2H-perfluoro-octylphosphonic acid, and other such phosphonic acid-based materials, and hexamethyldisilazane (HMDS) and other such disilazane-based compounds. There are no restrictions on the material so long as it is a chlorosilane-based material, alkoxysilane-based material, phosphonic acid-based material, or disilazane-based material that can form an SAM film.

In Modification Example 3, the bubbler 35 into which the vapor source 37 of the SAM precursor material is introduced is used, for example, when supplying a vapor of the SAM film raw material to the chamber 2 by allowing a carrier gas such as nitrogen (N₂) to flow, without heating the SAM film raw material. The bubbler 35 is connected to a pipe through which the carrier gas is supplied from the carrier gas introduction port 32 for carrying a vapor of the vapor source 37 via the flow control valve/mass flow controller 33, and the piping is configured to have the bypass valve 34 through which a carrier gas that can be mixed with the vapor from the bubbler passes, without passing through the bubbler 35. If no carrier gas is required, the carrier gas need not be supplied.

With the SAM film raw material bubbler 35, an evaporation source for dehydration condensation between the OH groups formed on the surface of the sample S and the OH groups produced by hydrolysis of the precursor material of the SAM film, or an evaporation source for dehydration condensation between the OH groups formed on the surface of the sample S by the molecules themselves of the evaporation source of the SAM precursor material, is selected as the vapor source 37 for the SAM precursor material. Examples include 1H,1H,2H,2H-perfluorodecyldimethylchlorosilane, tetrahydrooctylmethyldichlorosilane (FOMDS), dichlorodimethylsilane (DDMS), 1H,1H,2H,2H-perfluorodecyltrichlorosilane (FDTS), octadecyltrichlorosilane (OTS), tetrahydrooctyltrichlorosilane (FOTS), and other such chlorosilane-based compounds, dimethyldimethoxysilane, dimethyldiethoxysilane, isobutylmethyldimethoxysilane, hexyltrimethoxysilane, hexyltriethoxysilane, dodecyltriethoxysilane, 1H,1H,2H,2H-perfluorodecyltrimethoxysilane, n-octadecyltrimethoxysilane, tetraethoxysilane (TEOS), and other such alkoxysilane compounds, octadecylphosphonic acid, 1H,1H,2H,2H-perfluoro-octylphosphonic acid, and other such phosphonic acid-based materials, and hexamethyldisilazane (HMDS) and other such disilazane-based compounds. There are no restrictions on the material so long as it is a chlorosilane-based material, alkoxysilane-based material, phosphonic acid-based material, or disilazane-based material that can form an SAM film.

In Modification Example 3, the bubbler 45 into which the vapor source 47 of the SAM precursor material is introduced is used, for example, when supplying a vapor of the SAM film raw material to the chamber 2 by allowing a carrier gas such as nitrogen (N₂) to flow, without heating the SAM film raw material. The bubbler 45 is connected to a pipe through which the carrier gas is supplied from the carrier gas introduction port 42 for carrying a vapor of the vapor source 47 via the flow control valve/mass flow controller 43, and the piping is configured to have the bypass valve 44 through which a carrier gas that can be mixed with the vapor from the bubbler passes, without passing through the bubbler 45. If no carrier gas is required, the carrier gas need not be supplied.

With the SAM film raw material bubbler 45, an evaporation source for dehydration condensation between the OH groups formed on the surface of the sample S and the OH groups produced by hydrolysis of the precursor material of the SAM film, or an evaporation source for dehydration condensation between the OH groups formed on the surface of the sample S by the molecules themselves of the evaporation source of the SAM precursor material, is selected as the vapor source 47 for the SAM precursor material. Examples include 1H,1H,2H,2H-perfluorodecyldimethylchlorosilane, tetrahydrooctylmethyldichlorosilane (FOMDS), dichlorodimethylsilane (DDMS), 1H,1H,2H,2H-perfluorodecyltrichlorosilane (FDTS), octadecyltrichlorosilane (OTS), tetrahydrooctyltrichlorosilane (FOTS), and other such chlorosilane-based compounds, dimethyldimethoxysilane, dimethyldiethoxysilane, isobutylmethyldimethoxysilane, hexyltrimethoxysilane, hexyltriethoxysilane, dodecyltriethoxysilane, 1H,1H,2H,2H-perfluorodecyltrimethoxysilane, n-octadecyltrimethoxysilane, tetraethoxysilane (TEOS), and other such alkoxysilane compounds, octadecylphosphonic acid, 1H,1H,2H,2H-perfluoro-octylphosphonic acid, and other such phosphonic acid-based materials, and hexamethyldisilazane (HMDS) and other such disilazane-based compounds. There are no restrictions on the material so long as it is a chlorosilane-based material, alkoxysilane-based material, phosphonic acid-based material, or disilazane-based material that can form an SAM film.

### Working Example 1

### Comparative Example

In the apparatus of Modified Example 1, which involves the laminate manufacturing apparatus 200 shown in FIGS. 2 and 3, a substrate S made of SiO₂ (glass) (comparative sample) was placed on the lower electrode 3 in the vacuum chamber 2 and covered with the upper chamber 27, so that the upper electrode 4 was parallel to and opposite the lower electrode 3.

A step of imparting OH groups to the surface of the comparative sample was conducted. The atmospheric pressure in the vacuum chamber 2 was lowered to 5 to 10 Pa. After that, the mantle heater 16 was used to heat the bubbler 15 containing water (H₂O) as the vapor source 17, which is a reactant substance necessary for the plasma treatment and the SAM film formation process, to 70° C., and the water vapor was introduced into the chamber 2 so that the atmospheric pressure in the vacuum chamber 2 reached 100 Pa. A high-frequency power source of 13.56 MHz was used as the plasma generation power source 7, and water vapor plasma irradiation was performed for 3 minutes at a power of 200 W.

After the water vapor plasma irradiation, the vacuum chamber 2 was opened to the atmosphere, and the contact angle of water on the SiO₂ substrate of the comparative sample was measured and found to be 5° or less, confirming that the surface treatment was super hydrophilic, to the extent that the limit of measurement was exceeded.

However, when the SAM film was formed on the substrate surface by opening the vacuum chamber 2 to the atmosphere after the substrate surface had been rendered hydrophilic, it took a very long time to form the SAM film. Therefore, this SAM film formation would not be well suited to an industrial application.

### Working Example

In the apparatus of Modified Example 1 based on the laminate manufacturing apparatus 200 shown in FIGS. 2 and 3, a substrate made of SiO₂ (glass), which was the sample S, was placed on the lower electrode 3 in the chamber 2 and covered with the upper chamber 27, so that the upper electrode 4 was parallel to and opposite the lower electrode 3.

A step of imparting OH groups to the surface of the sample S was conducted by the same method as in the comparative example. That is, the atmospheric pressure in the chamber 2 was lowered to 5 to 10 Pa. After that, the mantle heater 16 was used to heat the bubbler 15 containing water (H₂O) as the vapor source 17, which is a reactant substance necessary for the plasma treatment and the SAM film formation process, to 70° C., and the water vapor was introduced into the chamber 2 so that the atmospheric pressure in the vacuum chamber 2 reached 100 Pa. A high-frequency power source of 13.56 MHz was used as the plasma generation power source 7, and water vapor plasma irradiation was performed for 3 minutes at a power of 200 W.

The SAM film raw material chamber 18, which contained 5 cc of 1H,1H,2H,2H-perfluorooctyltrimethoxysilane as the vapor source 20 for the SAM precursor material, was heated to 50° C. with the mantle heater 19. Upon completion of the plasma irradiation, the valve of the bubbler 15 was closed, after which the valve of the SAM film raw material chamber 18 was opened without opening the vacuum chamber 2 to the atmosphere, thereby introducing 1H,1H,2H,2H-perfluorooctyltrimethoxysilane vapor into the vacuum chamber 2, and the SiO₂ substrate of the sample S was exposed to the 1H,1H,2H,2H-perfluorooctyltrimethoxysilane vapor for 20 minutes to form an SAM film on the sample.

The valve of the SAM film raw material chamber 18 closed, after which the vacuum chamber 2 was opened to the atmosphere, and the contact angle of water on the sample substrate S was measured, thereby confirming that a water-repellent treatment of 99° had been performed on the sample substrate S. Therefore, it was confirmed that an SAM film of a 1H,1H,2H,2H-perfluorooctylsiloxane derivative had been formed in a high density.

It was confirmed from the above results that an SAM film can be simply, easily formed with good reproducibility, and a laminate can be manufactured, by using the laminate manufacturing apparatus of the present invention.

The present invention was described above through a preferred embodiment, but this description is not intended to be limiting in nature, and various modifications are of course possible. For instance, in the above embodiment, the surface hydrophilization mode and the self-assembly mode were performed in the same vacuum chamber, without opening the vacuum chamber to the atmosphere, but the vacuum chamber may be opened to the atmosphere following the surface hydrophilization mode, after which the self-assembling mode may be performed in a different vacuum chamber, although this does take longer to form an SAM film.

1. A laminate manufacturing apparatus for forming a self-assembled monolayer on a film formation surface of a substrate, the laminate manufacturing apparatus comprising:
a vacuum chamber in which the substrate is configured to be housed;
a gas introduction port configured to introduce a gas into the vacuum chamber; and
a plasma generator configured to generate a plasma atmosphere in the vacuum chamber,
the laminate manufacturing apparatus having
a surface hydrophilization mode in which the film formation surface of the substrate is modified by the plasma atmosphere generated by the plasma generator in a state in which an evaporation source that imparts a hydrophilic group is supplied into the vacuum chamber, thereby rendering the film formation surface hydrophilic, and
a self-assembling mode in which an evaporation source of a precursor material of the self-assembled monolayer is supplied to the substrate on which the film formation surface has been hydrophilized, in a state in which an evaporation source that promotes hydrolysis of the precursor material of the self-assembled monolayer has been supplied while an inside of the vacuum chamber is under a vacuum, thereby forming the self-assembled monolayer on the hydrophilized film formation surface.

2. The laminate manufacturing apparatus according to claim 1, wherein
the surface hydrophilization mode and the self-assembling mode are performed in the same vacuum chamber.

3. The laminate manufacturing apparatus according to claim 1, wherein
a transition from the surface hydrophilization mode to the self-assembling mode is performed without opening the vacuum chamber to the atmosphere.

4. The laminate manufacturing apparatus according to claim 1, wherein
the evaporation source that imparts the hydrophilic group to the film formation surface of the substrate, and the evaporation source that promotes the hydrolysis of the precursor material of the self-assembled monolayer are both water vapor.

5. The laminate manufacturing apparatus according to claim 4, wherein
the water vapor in the self-assembling mode is water vapor left over from the surface hydrophilization mode.

6. The laminate manufacturing apparatus according to claim 1, wherein
the plasma generator is configured such that a lower electrode that serves as a stage on which the substrate is placed and an upper electrode that is disposed opposite the lower electrode are formed as plasma generation electrodes.

7. The laminate manufacturing apparatus according to claim 4, wherein
the evaporation source of the precursor material of the self-assembled monolayer film is supplied from the gas introduction port.

8. The laminate manufacturing apparatus according to claim 6, wherein
a ground ring is provided around the stage so as to leave a gap through which the gas in the vacuum chamber is discharged.

9. The laminate manufacturing apparatus according to claim 1, further comprising
a bubbler provided to a gas pipe that is connected to the gas introduction port.

10. A method for forming a self-assembled monolayer on a surface of a substrate, the method comprising:
disposing the substrate in a vacuum chamber;
rendering the surface of the substrate hydrophilic by supplying an evaporation source that imparts a hydrophilic group to the surface of the substrate into the vacuum chamber and by plasmatizing an interior of the vacuum chamber to generate a plasma of the evaporation source; and
forming the self-assembled monolayer on the surface of the substrate by supplying an evaporation source of a precursor material of the self-assembled monolayer into the vacuum chamber in a state in which an evaporation source that promotes hydrolysis of the precursor material of the self-assembled monolayer has been supplied after the rendering of the surface of the substrate hydrophilic,
the rendering of the surface of the substrate hydrophilic and the forming of the self-assembled monolayer being performed without opening the vacuum chamber to the atmosphere.

11. A laminate manufacturing apparatus for forming a self-assembled monolayer on a film formation surface of a substrate, the laminate manufacturing apparatus comprising:
a vacuum chamber in which the substrate is configured to be installed, the vacuum chamber having
a gas introduction port that is configured to introduce a gas into the vacuum chamber,
a vacuum exhaust port, and
a pressure gauge that is configured to monitor pressure in the vacuum chamber,
a lower electrode stage disposed inside the vacuum chamber and connected to a power source for plasma generation;
an upper electrode disposed inside the vacuum chamber and serving as a gas shower plate that is opposite the lower electrode stage and installed on an inner wall surface of the vacuum chamber, the vacuum chamber, the lower electrode stage and the upper electrode having a function of a vacuum plasma treatment process with the inner wall surface serving as a ground surface; and
at least two systems of gas introduction pipes connected to the gas introduction ports for a plasma generation gas and a raw material gas for the self-assembled monolayer,
introduced gases being switched or mixed when switching a process.

12. The laminate manufacturing apparatus according to claim 11, wherein
the upper electrode and/or the lower electrode stage functions as a sample stage.

13. The laminate manufacturing apparatus according to claim 11, wherein
the number of the systems of the gas introduction pipes is at least three and no more than five.
